(19) United States
(12) Patent Application Publication
(10) Pub. No.: US 2014/0180060 A1
(43) Pub. Date: Jun. 26, 2014

(54) Methods and Systems for Automated Functional MRI in Clinical Applications

(71) Applicants: Todd Parrish, Evanston, IL (US); Bruce S. Spottiswoode, Chicago, IL (US)

(72) Inventors: Todd Parrish, Evanston, IL (US); Bruce S. Spottiswoode, Chicago, IL (US)

(21) Appl. No.: 14/103,196

(22) Filed: Dec. 11, 2013

Related U.S. Application Data
(60) Provisional application No. 61/737,868, filed on Dec. 17, 2012.

(51) Int. Cl. G01R 33/48

(52) U.S. Cl. CPC G01R 33/4806
USPC 600/411; 600/410

(57) ABSTRACT

A method for operating an automated functional Magnetic Resonance Imaging (fMRI) system includes controlling, by a control computer, a Magnetic Resonance Imaging (MRI) device to apply one or more pulse sequences to a portion of a brain of a patient and controlling, by the control computer, one or more stimulation devices to provide a stimulation of the patient. The method also includes acquiring, by the control computer, functional images of said portion of said brain of the patient in response to the applying of the one or more pulse sequences and during stimulation and receiving, by the control computer, one or more patient responses during the stimulating of the patient. The method further includes synchronizing, by the control computer, the stimulation of the patient, the acquiring of the functional images and the receiving of the one or more patient responses using at least one synchronization signal.

### CROSS-REFERENCE TO RELATED APPLICATIONS

The present application claims priority to U.S. provisional application Ser. No. 61/737,868 filed Dec. 17, 2012, which is incorporated herein by reference in its entirety.

### TECHNOLOGY FIELD

The present application relates generally to methods, systems, and apparatuses for operating an automated functional Magnetic Resonance Imaging (fMRI) system, and in particular, to methods, systems, and apparatuses for synchronizing, by a control computer, stimulation of the patient, acquiring of functional images and receiving patient responses using at least one synchronization signal.

### BACKGROUND

Functional magnetic resonance imaging (“fMRI”) is a magnetic resonance imaging (“MRI”) method for estimating regional brain activity during a predefined cognitive task. While fMRI has contributed significantly to the field of neuroscience, clinical applications have been slower to adapt and use it because of the required extra components and the lack of an efficient automated process for performing fMRI measurements in a clinical setting.

Some conventional clinical application methods include pre-surgical planning, providing patients with a more informed decision process about treatments, and clinical outcomes in epilepsy treatment. In a standard setting, fMRI experiments typically involve peripheral hardware and software, as well as expertise for processing the fMRI data.

### SUMMARY

Embodiments of the present invention include a method for operating an automated functional Magnetic Resonance Imaging (fMRI) system. The method includes controlling, by a control computer, a Magnetic Resonance Imaging (MRI) device to apply one or more pulse sequences to a portion of a brain of a patient and controlling, by the control computer, one or more stimulation devices to provide a stimulation of the patient. The method also includes acquiring, by the control computer, functional images of said portion of said brain of the patient in response to the applying of the one or more pulse sequences and during stimulation and receiving, by the control computer, one or more patient responses during the stimulating of the patient. The method further includes synchronizing, by the control computer, the stimulation of the patient, the acquiring of the functional images and the receiving of the one or more patient responses using at least one synchronization signal.

According to one embodiment, the method further includes providing, by the control computer, post processing information that combines an acquired functional image of said acquired functional images with an acquired structural anatomical image.

In one embodiment, providing, by the control computer, said post processing information further includes providing a combined image by aligning, co-registering and combining the acquired functional image of said acquired functional images with the structural anatomical image using a common scanner coordinate framework.

In another embodiment, providing, by the control computer, said post processing information further includes providing a combined image by aligning, co-registering and combining the acquired functional image of said acquired functional images with an acquired structural anatomical image using a common scanner coordinate framework.

According to one embodiment, controlling, by the control computer, one or more stimulation devices to provide a stimulation of a patient comprises controlling a visual presentation device to visually present a cognitive task to the patient.

According to another embodiment, controlling a visual presentation device to visually present a cognitive task to the patient further includes controlling said visual presentation device to at least one of: (a) vary light in an MRI scanner bore; (b) output the cognitive task to a video device mounted in said MRI scanner bore; and (c) project the cognitive task onto a screen such that the cognitive task is viewable by said patient.

In one embodiment, controlling, by the control computer, one or more stimulation devices to provide a stimulation of a patient includes controlling a sound reproduction device to provide a sensory or cognitive auditory based task to said patient.

In an aspect of an embodiment, controlling a sound reproduction device further to provide a sensory or cognitive auditory based task to said patient further includes controlling said sound reproduction device to provide predetermined voice commands issued through an audio system to guide the patient through tasks including at least one of motor tasks, speech tasks, memory tasks and auditory tasks.

According to one embodiment, receiving, at the control computer, one or more patient responses during the stimulating of the patient further includes receiving a patient electrocardiogram (ECG).

According to another embodiment, synchronizing, by the control computer, further includes deriving said at least one synchronization signal from a single system clock signal.

Embodiments of the present invention include an automated functional Magnetic Resonance Imaging (fMRI) system that includes a patient stimulation device configured to stimulate a patient and a Magnetic Resonance Imaging (MRI) acquisition device configured to acquire functional images of a portion of a brain of said patient in response to a pulse sequence and during stimulation by said stimulation device. The system also includes a stimulation response measurement device configured to record patient response to said stimulation during said stimulation by said stimulation device and a control computer configured to mutually synchronize: (i) application of stimulation to said patient by said stimulation device; (ii) acquisition of magnetic resonance (MR) images by said MRI acquisition device; and (iii) recording patient response to said stimulation, using at least one synchronization signal.

According to one embodiment, the patient stimulation device configured to stimulate said patient includes a visual presentation device for presenting a cognitive task to said patient.

According to another embodiment, the patient stimulation device configured to stimulate said patient includes a sound reproduction device for providing a sensory or cognitive auditory based task to said patient.

In one embodiment, the patient stimulation device is controlled automatically by an MRI scanner console.

In another embodiment, the stimulation response measurement device records and gauges patient response during a stimulation task in response to patient interaction with at least one of (a) a pneumatic squeeze ball, (b) a respiratory bellows and (c) a separate response measurement device using, buttons, mouse or joystick.

According to one embodiment, the control computer further includes: (i) a repository having structural anatomical image data of said portion of said brain; and (ii) an image data processor configured to align, co-register, and combine an acquired functional image of said portion of said brain with a structural anatomical image acquired from said repository. The acquired functional image and said structural anatomical image are acquired using a common scanner coordinate framework to provide a combined image.

In an aspect of an embodiment, the image data processor applies functions include at least one of, (a) motion correction, (b) slice timing correction, (c) image spatial smoothing, (d) temporal filtering and (e) linear model fitting, to said acquired functional data to form a functional map.

In another aspect of an embodiment, the image data processor applies a predetermined threshold to the functional image data in determining brain areas active in response to said stimulation and applies a visual attribute to the determined active brain areas.

In yet another aspect of an embodiment, the image data processor derives and associates a confidence level to the determined active brain areas indicating a degree of confidence in identified active brain area being active in response to said stimulation.

According to one embodiment, the image data processor applies a plurality of predetermined thresholds to the functional image data in determining brain areas active in response to said stimulation and applies visual attributes to the determined active brain areas distinguishing relative degree of activity of said brain areas. The visual attributes include at least one of, color, highlighting, shading, patterns and symbols.

According to one embodiment, the control computer further includes: (i) a repository including structural anatomical image data of said portion of said brain; and (ii) an image data processor configured to align, co-register, and combine an acquired functional image of said portion of said brain and a structural anatomical image acquired from said repository with a common space. The acquired functional image and said structural anatomical image are acquired using a common scanner coordinate framework.

Embodiments of the present invention include an article of manufacture for operating an automated functional Magnetic Resonance Imaging (fMRI) system. The article of manufacture includes a non-transitory, tangible computer-readable medium holding computer-executable instructions for performing a method. The method includes controlling a Magnetic Resonance Imaging (MRI) device to apply one or more pulse sequences to a portion of a brain of a patient and controlling one or more stimulation devices to provide a stimulation of the patient. The method also includes acquiring functional images of said portion of said brain of the patient in response to the applying of the one or more pulse sequences and during stimulation and receiving one or more patient responses during the stimulating of the patient. The method further includes synchronizing the stimulation of the patient, the acquiring of the functional images and the receiving of the one or more patient responses using at least one synchronization signal.

### BRIEF DESCRIPTION OF THE DRAWINGS

FIG. 1 is a system diagram illustrating an exemplary system for performing fMRI measurements for use with embodiments disclosed herein;

FIG. 2 is a system flow diagram illustrating functions performed by the exemplary MRI scanner control computer shown in FIG. 1 for use with embodiments disclosed herein;

FIG. 3 is an illustration showing synchronization of patient stimuli, MRI sequence timing and patient response measurements for use with embodiments disclosed herein;

FIG. 4 illustrates an exemplary computing environment within which embodiments of the invention may be implemented; and

FIG. 5 is a flow diagram illustrating an exemplary method for operating an fMRI system for use with embodiments disclosed herein.

### DETAILED DESCRIPTION

Conventional fMRI measurement systems use intrinsic hardware that is internal to an MRI scanning area (e.g., in the scanner room or in proximity to the scanner), such as an MRI scanner, an MRI scanner control computer and an MRI image reconstruction computer. In these conventional systems, MRI scanner receives control data (e.g., MRI pulse sequence timing) from MRI scanner control computer, performs scans of a patient and sends raw data corresponding to the scans to MRI image reconstruction computer. MRI image reconstruction computer receives the raw data sent from MRI scanner and sends reconstructed image data, based on the raw data, to MRI scanner control computer. Control computer may then control MRI scanner to perform additional scans based on the received reconstructed images.

Conventional fMRI measurement systems, however, typically require costly and complex extrinsic peripheral hardware (and software) external to the MRI scanning area to stimulate patients to perform tasks, record response measurements and present information to operators. Examples of this costly and complex extrinsic peripheral hardware of conventional fMRI measurement systems include image projection equipment, auditory equipment and response measurement equipment, a post processing computer and a presentation computer.

Further, extrinsic peripheral hardware of these conventional fMRI measurement systems typically require one or more experts (e.g., radiologists or MRI technologists) to operate the external peripheral hardware, who may have limited time (and expertise) available to oversee scanning and post processing. In addition, the conventional systems may not provide immediate (e.g., online) fMRI activation results following the scan.

In a typical conventional fMRI measurement system, a presentation computer receives instructions, such as fMRI paradigm settings, and causes image projection equipment to visually present cognitive tasks to a subject patient and/or auditory equipment to aurally present tasks to the patient, thereby stimulating a patient to perform tasks. Response measurement equipment receives and stores responses during the stimulation to monitor patient cooperation during an fMRI task. Presentation computer receives the response measurement data from the response measurement equipment, indicating measurements of the patient during the stimulation.

With the assistance of an expert operator (e.g., instruct the patient verbally, open and run the correct paradigm, start and stop and physiological data logging, ensure synchronicity with the MRI sequence, and export results (images, subject response, physiological measurements etc.) for off-line analysis), presentation computer may then synchronize an fMRI task with an MRI scan, responsive to receiving a trigger signal sent at intervals (e.g., every TR) from MRI scanner control computer. When an fMRI scan is completed, the MRI images, task timing, and patient response measurements (e.g., patient response summary) may be sent to a post processing computer.

Post processing computer receives instructions, such as post processing settings 120, for applying post processing functions. Post processing functions may include motion correction, slice timing correction, image spatial smoothing, temporal filtering and linear model fitting. With the assistance of an expert (e.g., run the above described processing steps, and co-register the images to the subject's structural MRI scan or a standard brain template, and display the images after applying a statistical threshold.), post processing computer may then present, to the expert, fMRI statistical parametric activation maps, which may indicate regional brain activity during the task and displayed after applying a user-defined statistical threshold, or spatial locations in the fMRI images where the voxel time courses represent (with a given statistical threshold) that of the cognitive task timing.

Embodiments of the present invention include an efficient and automated fMRI configuration that limits the use of costly and complex peripheral hardware. Embodiments of the present invention limit the use of on-site expert personnel typically required to operate the external peripheral hardware providing, thereby reducing costs, improving workflow and reducing technical errors during complex fMRI experiments. Embodiments of the present invention include a system that provides precise timing synchronization of imaging, task stimuli and monitoring of patient responses for clinical applications (e.g. pre-operative planning), neuroscience and other applications.

Embodiments of the present invention provide systems and methods that indicate fMRI tasks, monitor patient cooperation, and create functional maps. Embodiments of the present invention include systems and methods that provide a cost effective and practical means of using existing peripheral equipment with an MRI scanner to present a series of tasks for pre-operative planning. Embodiments of the present invention include a fully automated fMRI process that incorporates available MRI sequence and online post processing features. The results may be made substantially immediately available on an MRI scanner console.

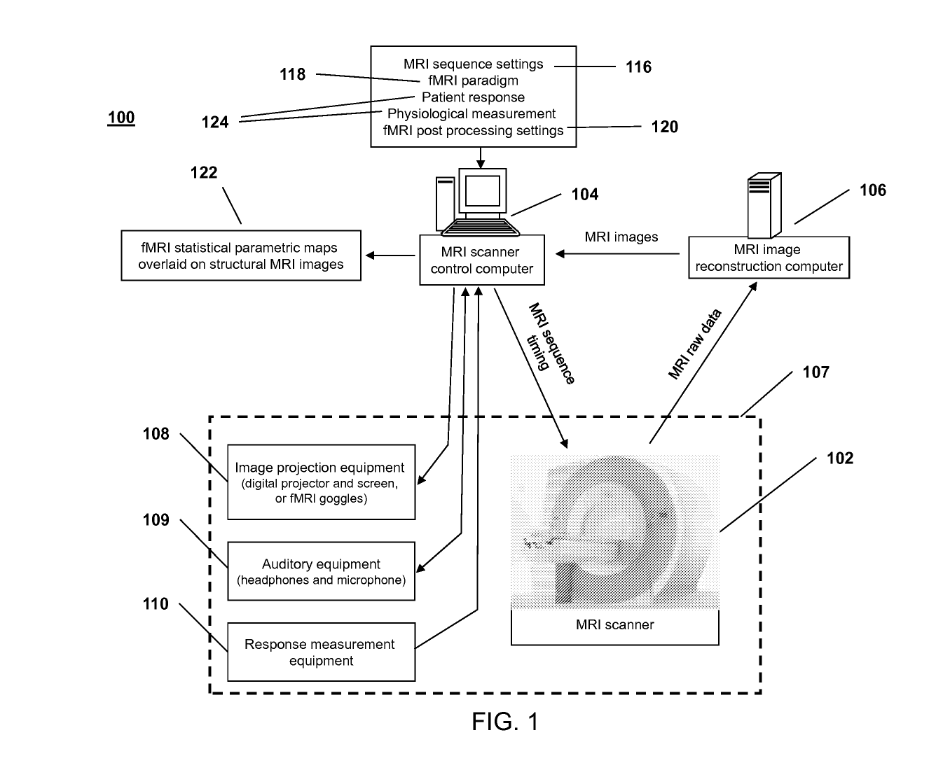

FIG. 1 is a system diagram illustrating an exemplary system 100 which may be used for performing pre-operative planning tasks in a clinical environment. As shown in FIG. 1, system 100 includes MRI scanner 102, MRI scanner control computer 104 and MRI image reconstruction computer 106. As shown, MRI scanner 102 is located within scanner room 107, along with image projection equipment 108, auditory equipment 109 and response measurement equipment 110. In contrast to conventional systems, however, MRI scanner control computer 104 may be used to directly control image projection equipment 108 and auditory equipment 109 and receive response measurements from response measurement equipment 110, thereby eliminating the use of additional complex and costly extrinsic presentation hardware, such as a presentation computer, which would otherwise require communication (e.g., receiving timing trigger signals) with MRI scanner control computer 104 to synchronize operations of system 100. In addition, independent costly software (e.g. fMRI paradigm settings) to operate the presentation computer (or other presentation equipment) and the presence of an expert to operate a presentation computer may be reduced or eliminated. In some embodiments, image projection equipment 108, auditory equipment 109 and response measurement equipment 110 may be part of scanner 102. Embodiments may include components of system 100 that are wirelessly connected or wired to one or more other components of system 100.

As shown in FIG. 1, MRI scanner control computer 104 may be also be configured to provide post processing data, such as fMRI statistical parametric maps overlaid on structural images, thereby eliminating the use of additional complex and costly extrinsic post processing hardware, such as a post processing computer. In addition, independent costly software (e.g. fMRI post processing settings) to operate a post processing computer (or other post processing equipment) and the presence of an expert to operate the presentation computer may be reduced or eliminated. In some embodiments, the MRI scanner control computer 104 may visually present information to the expert with a color coding of confidence level value. In other embodiments, a separately acquired high resolution structural MRI scan may also be performed to provide a detailed anatomical reference that is spatially aligned, co-registered and combined with the fMRI images.

MRI scanner control computer 104 may be configured to control the MRI scanner 102 and receive image data from MRI image reconstruction computer 106. MRI scanner 102 may be configured to receive, from MRI scanner control computer 104, control data, such as MRI sequence settings, which may include an image scanning protocol, such as a protocol defined for a T2* weighted echo planar imaging (EPI) with a repetition time (TR) of 1-2 seconds. MRI scanner 102 may perform scans of a portion (e.g., portion of a brain) of a patient and send raw data corresponding to the scans to MRI image reconstruction computer 106. MRI image reconstruction computer 106 may be configured to receive the raw data sent from MRI scanner 102 and send the reconstructed image data, based on the raw data, to MRI scanner control computer 104. MRI scanner control computer 104 control computer may then control MRI scanner to perform additional scans based on the received reconstructed images.

The MRI scanner 102 may include a RF (Radio Frequency) signal generator (not shown) and a magnetic field gradient generator (not shown). The RF signal generator may generate RF pulse sequences in anatomy (e.g. a portion of a brain) of a patient, enabling the scanner to subsequently acquire associated RF echo data. The magnetic field gradient generator may generate magnetic field gradients for anatomical volume selection, phase encoding, and readout RF data acquisition in a three dimensional (3D) anatomical volume.

In addition to receiving control instructions (e.g., MRI sequence settings 116) to control MRI scanner 102 and receive image data from MRI image reconstruction computer 106, MRI scanner control computer 104 may also incorporate MRI scanner hardware and software to automate the process of task stimulation and present immediate or substantially immediate online fMRI activation results, thereby providing a more efficient and less complex system.

For example, scanner control computer 104 may also include instructions (e.g., stored instructions) such as: (i) MRI sequence settings 116, (ii) fMRI paradigm settings 118; (iii) post processing instructions, such as post processing settings 120; and (iv) patient response and physiological measurements 124. Accordingly, control computer 104 in system 100 may be configured to: (i) directly control image projection equipment 108 and auditory equipment 109 to provide stimulation (via the fMRI paradigm settings 118) to a patient, in which the patient may perform one or more tasks in response to the stimulation; (ii) directly receive response measurement data, indicating measurements (e.g., indicating patient cooperation) of the patient performing a task, from response measurement equipment 110; and (ii) directly present post processing information, such as fMRI statistical parametric activation maps 122 or spatial locations in the fMRI images. In some embodiments, providing the stimulation may include providing instructions to the patient about a task the patient is about to perform, which may provide an accurate and consistent message to the patient and eliminate the required expertise of the operator.

That is, system 100 may advantageously provide stimuli within the MRI scanner room 107 via image projection equipment 108 and auditory equipment 109, which are controlled automatically by the MRI scanner control computer 104, as well as advantageously presenting post processing information directly by MRI scanner control computer 104. In this manner, system 100 may advantageously provide an efficient and automated fMRI configuration that limits the use of costly and complex peripheral hardware (e.g., a post processing computer and a presentation computer). In addition, system 100 may advantageously limit the use of on-site expert personnel to operate the external peripheral hardware. For example, fMRI measurements may be obtained and presented using a radiologist or MRI technician with limited fMRI experience to operate system 100.

In some embodiments, system 100 may use software controlled predetermined voice commands issued through an audio system used to communicate with the patient, which may be used to guide the patient through, for example, motor tasks, speech tasks, memory tasks, and auditory tasks. In some embodiments, system 100 may advantageously vary lighting in the MRI scanner bore rapidly to present visual stimuli and output data to a video projector mounted to the end of a MRI scanner magnet. In some embodiments, response measurement equipment 110 may be used to gauge patient cooperation during a fMRI task, such as cooperation via the use of a pneumatic squeeze ball or respiratory bellows (which are activated in response to verbal commands) and an electrocardiogram (ECG) system (which is used to measure skeletal muscle activity during motor tasks).

In some embodiments, system 100 may advantageously provide fMRI results substantially immediately to determine if more studies need to be completed. In some embodiments, the system may provide for rapid radiological reporting as patients concerned are often on the verge of surgery. For example, system 100 may be used to identify a spatial relationship between important functional areas in a brain and an area to be resected. Functional MRI results obtained via system 100 may be used to determine appropriateness of surgery and may influence entry point and trajectory of surgical intervention to avoid damaging eloquent cortical areas, which may cause symptomatic cognitive or motor deficits. Avoidance of such injury may substantially influence surgical outcome. In some embodiments, system 100 may be used when task timing is pre-determined. In other embodiments, system 100 may be used for event related and resting state fMRI methods.

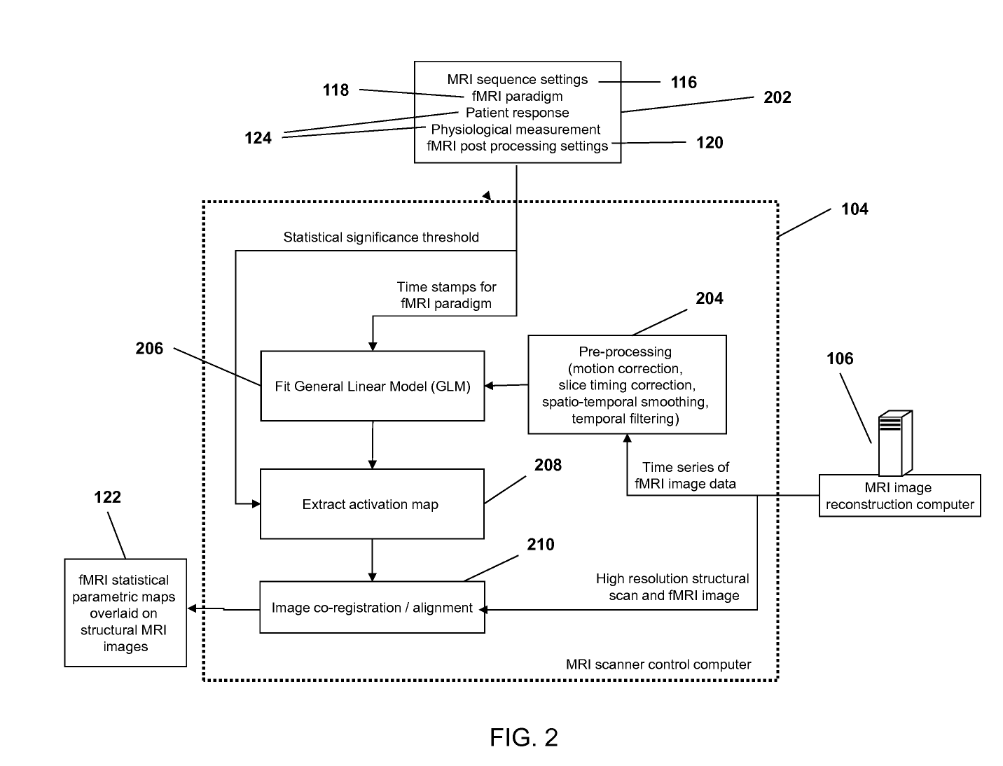

FIG. 2 is a system flow diagram illustrating various functions performed automatically by the exemplary MRI scanner control computer 104 shown in FIG. 1. As shown at step 202, scanner control computer 104 may receive sequence settings 116, instructions (e.g., fMRI paradigm settings 118), post processing instructions (e.g., post processing settings 120), as well as patient response and physiological measurements 124. As shown at step 204, image data processor 1120 of scanner control computer 104 may apply functions including at least one of, (a) motion correction, (b) slice timing correction, (c) image spatial smoothing, (d) temporal filtering and (e) linear model fitting, to the acquired functional data to form a functional map based on the received fMRI image data (e.g., time series of fMRI image data and high resolution structural scan and fMRI image) from image reconstruction computer 106.

Automated fMRI post processing may be automatically performed in response to fMRI task timing. For example, scanner control computer 104 may receive time stamps for fMRI paradigm (e.g., time of performance of cognitive tasks) to produce a fit general linear model (GLM), as shown at step 206. Scanner control computer 104 may also receive a statistical significance threshold to extract an activation map, as shown at step 208. Scanner control computer 104 may perform image co-registration and/or alignment using the activation map and the high resolution structural scan and fMRI image, as shown at step 210. Scanner control computer 104 may then provide post processing info, such as the fMRI statistical parametric maps overlaid on structural MRI images 122. In some embodiments, online post processing settings may be predetermined along with MRI sequence settings. Co-registration of the fMRI data to the high resolution structural MRI image (as an anatomical reference) may be facilitated by both sets of images being acquired using common scanner coordinates.

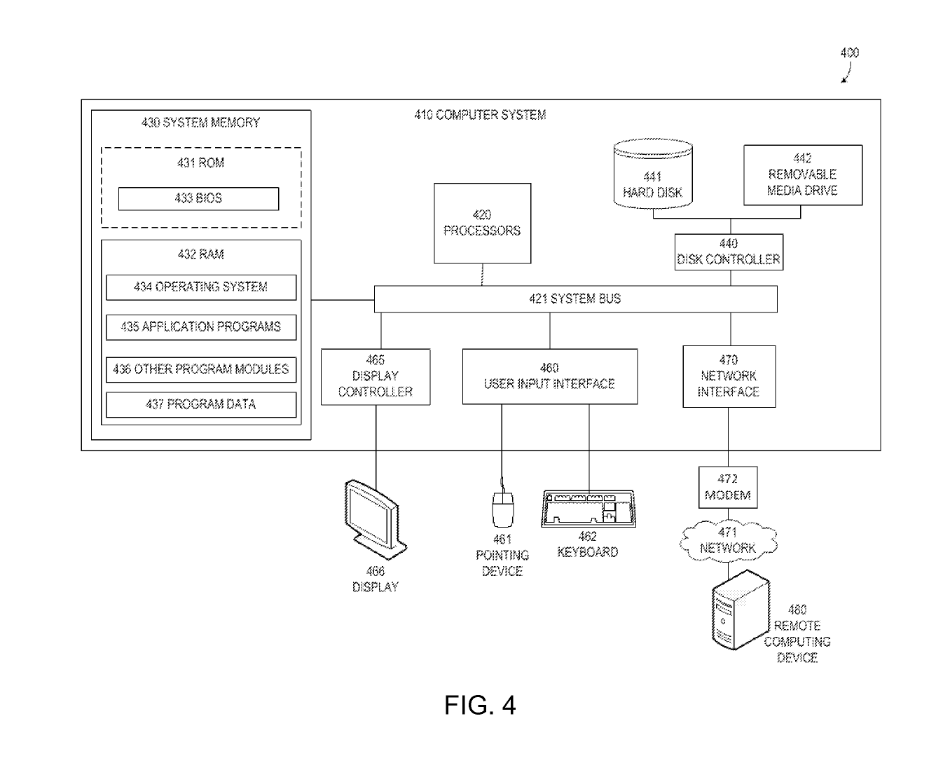

Scanner control computer 104 may include a repository (e.g., in hard disk 441 or removable media drive 442 shown in FIG. 4) including structural anatomical image data of a portion of a brain and an image data processor (e.g., one of processors 420 shown in FIG. 4) for aligning, co-registering and combining an acquired functional image of the portion of the brain with a structural anatomical image acquired from the repository. The acquired functional image and said structural anatomical image may be acquired using a common scanner coordinate framework, to provide a combined image.

The image data processor may apply a predetermined threshold to the functional image data in determining brain areas active in response to stimulation and apply a visual attribute to the determined active brain areas. The image data processor may derive and associate a confidence level to the determined active brain areas indicating a degree of confidence in identified active brain area being active in response to the stimulation. In some embodiments, the image data processor may apply a plurality of predetermined thresholds to the functional image data in determining brain areas active in response to the stimulation and apply visual attributes to the determined active brain areas distinguishing relative degree of activity of the brain areas. The visual attributes may include at least one of, color, highlighting, shading, patterns and symbols.

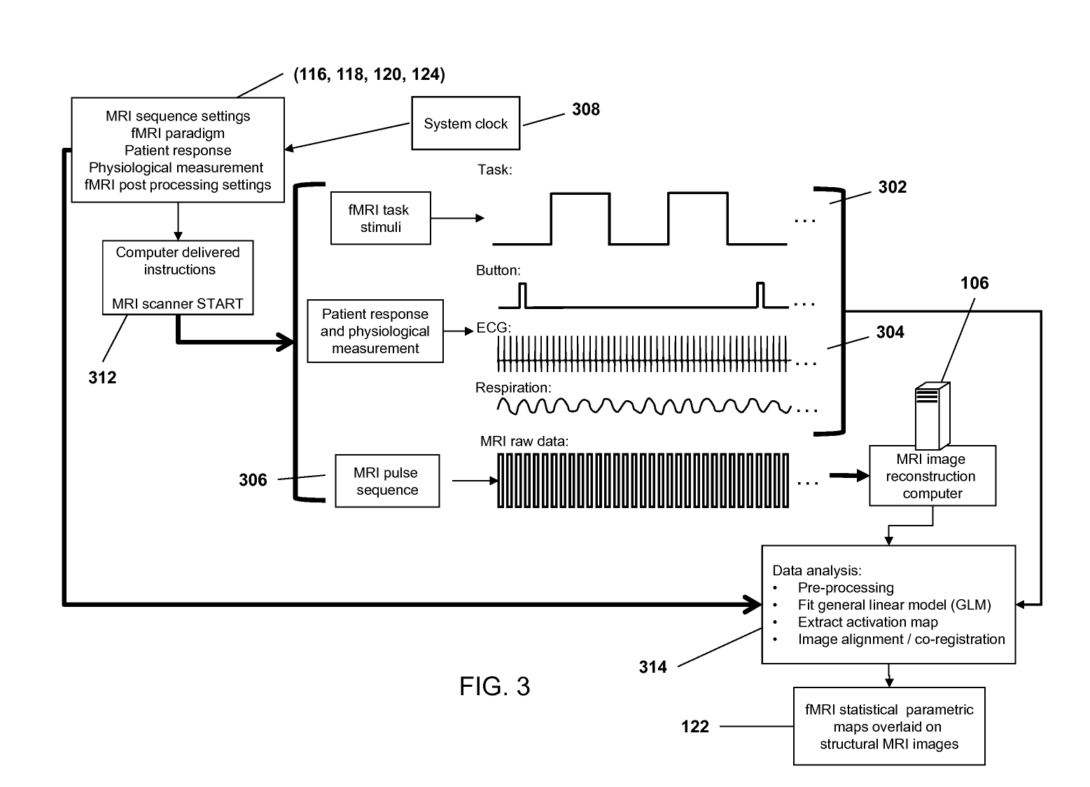

FIG. 3 is an illustration showing synchronization of patient stimuli, MRI sequence timing and patient response measurements for use with embodiments disclosed herein. In this manner, scanner control computer 104 may act as a synchronization unit that mutually synchronizes stimulation of a patient, acquiring functional images of a portion of a brain of the patient during stimulation, and receipt of response measurements of patient responses using at least one synchronization signal via a system clock 308 within scanner control computer 104. Accordingly, embodiments may advantageously provide precise timing synchronization of imaging, task stimuli and monitoring of patient responses for clinical applications (e.g., pre-operative planning), neuroscience and other applications.

As shown in FIG. 3, a computer, such as control computer 104, may receive instructions such as MRI sequencing 116, fMRI task stimuli (e.g., paradigm or task) 118, patient response measurements (e.g. button press), physiological measurement (e.g., ECG, respiration, skin conductance) 120 and fMRI post processing 124. Having received the instructions, control computer 104 may control MRI scanner to perform scans of a portion (e.g., portion of a brain) of a patient, as shown at block 312. Using system clock 308, control computer 104 may then synchronize the fMRI task stimuli shown at the first timing pattern 302, patient response measurements (e.g. button press) and physiological measurement (e.g. ECG, respiration, skin conductance) shown at second timing patterns 304, as well as MRI sequencing shown at third timing pattern 306.

For example, the first timing pattern 302 indicates the timing of presentation of intrinsic stimuli to a patient to perform a task, with each cycle representing a period of time between multiple stimulations. The second timing patterns 304 indicate the timing of received response measurements and physiological measurements of the patient during simulation. The third timing pattern 306 indicates the timing of acquired images of a portion of a patient's brain, with each cycle representing a period of time between acquired images. Using the system clock 308, each task, responsive to intrinsic stimuli, may be synchronized with acquired images of the brain (via MRI sequence timing) and the received response measurements. In this manner, the synchronization may advantageously avoid temporal drift occurring between the MRI scanner control computer 104 and the presentation computer 114.

MRI image reconstruction computer 106 may receive the raw data sent from MRI scanner 102 and send the reconstructed image data, based on the raw data, to MRI scanner control computer 104. The timing via system clock 308 may then also be used for data analysis 314, such as fMRI post processing, to provide fMRI statistical parametric maps overlaid on structural MRI images 122.

In some embodiments, an operator may define an anatomical scan region and initiate the MRI sequence and in response to aural and/or visual tasks programmed into the MRI scanner, a system such as system 100 may provide a comprehensively automated fMRI measurement. When the task and scan is complete, the fMRI statistical parametric maps may be made available on the MRI scanner control computer 104. In some aspects, system 100 may advantageously prevent risk of loss of personal information and/or limit the use of non-FDA software. Further, an operator (e.g., MRI technologist) may assess image quality, apply a statistical threshold to the statistical parametric maps, and send images directly to a reporting radiologist via a hospital picture archiving and communication system (PACS).

In some embodiments, system 100 may synchronize fMRI activation maps and structural MRI acquisition and stimuli and response recording with a MRI pulse sequence. Further, systems, such as system 100 may advantageously limit an initial synchronization event as the same system clock is used to ensure temporal synchronicity throughout a fMRI measurement. In some embodiments, a common coordinate framework may be used to acquire fMRI activation map image data and MRI structural data and present non-image fMRI results recording data.

According to one exemplary embodiment, timing may use a synchronization event at the beginning of a scan. Image data post processing may use time stamps and an accumulation of multiples of the repetition time (TR) of the fMRI scan. The system may also be usable for event related, block design and resting state fMRI operation.

In some embodiments, system 100 may be used to efficiently improve patient informed decision making about their treatment, as well as clinical outcomes in epilepsy treatment. For example, system 100 may efficiently localize the source of a seizure or support the findings from electroencephalography (EEG) and may determine language and memory lateralization to aid in a decision process for surgery.

In some embodiments, system 100 may be used to more efficiently provide fMRI tasks for neurosurgical planning, such as tactile, motor, language and visual tasks and identify motor regions using passive tasks and even at rest using functional connectivity fMRI. System 100 may also be used to more efficiently provide language tasks and auditory tasks that may be used to determine speech dominance. In some embodiments, system 100 may also be used to more efficiently provide memory tasks that may be used to determine memory dominance or diagnosis of disease (e.g. Alzheimer's).

In some embodiments, system 100 may be used to more efficiently provide a non-invasive and safe procedure that can aid in the decision process to perform surgery and for planning of surgical approaches needed for lesion resection by identifying eloquent areas, as well as in the assessment of the feasibility of tumor resection and in identifying suitable candidates.

FIG. 4 illustrates an example of a computing environment 400 within which embodiments of the invention may be implemented. Computing environment 400 may include computer system 410, which is one example of a computing system upon which embodiments of the invention may be implemented. As shown in FIG. 4, the computer system 410 may include a communication mechanism such as a bus 421 or other communication mechanism for communicating information within the computer system 410. The system 410 further includes one or more processors 420 coupled with the bus 421 for processing the information. The processors 420 may include one or more CPUs, GPUs, or any other processor known in the art.

The computer system 410 also includes a system memory 430 coupled to the bus 421 for storing information and instructions to be executed by processors 420. The system memory 430 may include computer readable storage media in the form of volatile and/or nonvolatile memory, such as read only memory (ROM) 431 and/or random access memory (RAM) 432. The system memory RAM 432 may include other dynamic storage device(s) (e.g., dynamic RAM, static RAM, and synchronous DRAM). The system memory ROM 431 may include other static storage device(s) (e.g., programmable ROM, erasable PROM, and electrically erasable PROM). In addition, the system memory 430 may be used for storing temporary variables or other intermediate information during the execution of instructions by the processors 420. A basic input/output system 433 (BIOS) containing the basic routines that help to transfer information between elements within computer system 410, such as during start-up, may be stored in ROM 431. RAM 432 may contain data and/or program modules that are immediately accessible to and/or presently being operated on by the processors 420. System memory 430 may additionally include, for example, operating system 434, application programs 435, other program modules 436 and program data 437.

The computer system 410 also includes a disk controller 440 coupled to the bus 421 to control one or more storage devices for storing information and instructions, such as a magnetic hard disk 441 and a removable media drive 442 (e.g., floppy disk drive, compact disc drive, tape drive, and/or solid state drive). The storage devices may be added to the computer system 410 using an appropriate device interface (e.g., a small computer system interface (SCSI), integrated device electronics (IDE), Universal Serial Bus (USB), or FireWire).

The computer system 410 may also include a display controller 465 coupled to the bus 421 to control a display or monitor 466, such as a cathode ray tube (CRT) or liquid crystal display (LCD), for displaying information to a computer user. The computer system includes an input interface 460 and one or more input devices, such as a keyboard 462 and a pointing device 461, for interacting with a computer user and providing information to the processor 420. The pointing device 461, for example, may be a mouse, a trackball, or a pointing stick for communicating direction information and command selections to the processor 420 and for controlling cursor movement on the display 466. The display 466 may provide a touch screen interface which allows input to supplement or replace the communication of direction information and command selections by the pointing device 461.

The computer system 410 may perform a portion or all of the processing steps of embodiments of the invention in response to the processors 420 executing one or more sequences of one or more instructions contained in a memory, such as the system memory 430. Such instructions may be read into the system memory 430 from another computer readable medium, such as a hard disk 441 or a removable media drive 442. The hard disk 441 may contain one or more datastores and data files used by embodiments of the present invention. Datastore contents and data files may be encrypted to improve security. The processors 420 may also be employed in a multi-processing arrangement to execute the one or more sequences of instructions contained in system memory 430. In alternative embodiments, hard-wired circuitry may be used in place of or in combination with software instructions. Thus, embodiments are not limited to any specific combination of hardware circuitry and software.

As stated above, the computer system 410 may include at least one computer readable medium or memory for holding instructions programmed according to embodiments of the invention and for containing data structures, tables, records, or other data described herein. The term “computer readable medium” as used herein refers to any non-transitory, tangible medium that participates in providing instructions to the processor 420 for execution. A computer readable medium may take many forms including, but not limited to, non-volatile media, volatile media, and transmission media. Non-limiting examples of non-volatile media include optical disks, solid state drives, magnetic disks, and magneto-optical disks, such as hard disk 441 or removable media drive 442. Non-limiting examples of volatile media include dynamic memory, such as system memory 430. Non-limiting examples of transmission media include coaxial cables, copper wire, and fiber optics, including the wires that make up the bus 421. Transmission media may also take the form of acoustic or light waves, such as those generated during radio wave and infrared data communications.

The computing environment 400 may further include the computer system 420 operating in a networked environment using logical connections to one or more remote computers, such as remote computer 480. Remote computer 480 may be a personal computer (laptop or desktop), a mobile device, a server, a router, a network PC, a peer device or other common network node, and typically includes many or all of the elements described above relative to computer 410. When used in a networking environment, computer 410 may include modem 462 for establishing communications over a network 461, such as the Internet. Modem 462 may be connected to system bus 421 via user network interface 470, or via another appropriate mechanism.

Network 471 may be any network or system generally known in the art, including the Internet, an intranet, a local area network (LAN), a wide area network (WAN), a metropolitan area network (MAN), a direct connection or series of connections, a cellular telephone network, or any other network or medium capable of facilitating communication between computer system 410 and other computers (e.g., remote computing system 480). The network 471 may be wired, wireless or a combination thereof. Wired connections may be implemented using Ethernet, Universal Serial Bus (USB), RJ-11 or any other wired connection generally known in the art. Wireless connections may be implemented using Wi-Fi, WiMAX, and Bluetooth, infrared, cellular networks, satellite or any other wireless connection methodology generally known in the art. Additionally, several networks may work alone or in communication with each other to facilitate communication in the network 471.

An executable application, as used herein, comprises code or machine readable instructions for conditioning the processor to implement predetermined functions, such as those of an operating system, a context data acquisition system or other information processing system, for example, in response to user command or input. An executable procedure is a segment of code or machine readable instruction, sub-routine, or other distinct section of code or portion of an executable application for performing one or more particular processes. These processes may include receiving input data and/or parameters, performing operations on received input data and/or performing functions in response to received input parameters, and providing resulting output data and/or parameters. A graphical user interface (GUI), as used herein, comprises one or more display images, generated by a display processor and enabling user interaction with a processor or other device and associated data acquisition and processing functions.

The GUI also includes an executable procedure or executable application. The executable procedure or executable application conditions the display processor to generate signals representing the GUI display images. These signals are supplied to a display device which displays the image for viewing by the user. The executable procedure or executable application further receives signals from user input devices, such as a keyboard, mouse, light pen, touch screen or any other means allowing a user to provide data to a processor. The processor, under control of an executable procedure or executable application, manipulates the GUI display images in response to signals received from the input devices. In this way, the user interacts with the display image using the input devices, enabling user interaction with the processor or other device. The functions and process steps herein may be performed automatically or wholly or partially in response to user command. An activity (including a step) performed automatically is performed in response to executable instruction or device operation without user direct initiation of the activity.

The system and processes of the figures presented herein are not exclusive. Other systems, processes and menus may be derived in accordance with the principles of the invention to accomplish the same objectives. Although this invention has been described with reference to particular embodiments, it is to be understood that the embodiments and variations shown and described herein are for illustration purposes only. Modifications to the current design may be implemented by those skilled in the art, without departing from the scope of the invention. Further, the processes and applications may, in alternative embodiments, be located on one or more (e.g., distributed) processing devices on a network linking the units of FIG. 1. Any of the functions and steps provided in the Figures may be implemented in hardware, software or a combination of both. No claim element herein is to be construed under the provisions of 35 U.S.C. 112, sixth paragraph, unless the element is expressly recited using the phrase “means for.”

The embodiments of the present disclosure may be implemented with any combination of hardware and software. In addition, the embodiments of the present disclosure may be included in an article of manufacture (e.g., one or more computer program products) having, for example, computer-readable, non-transitory media. The media has embodied therein, for instance, computer readable program code for providing and facilitating the mechanisms of the embodiments of the present disclosure. The article of manufacture can be included as part of a computer system or sold separately.

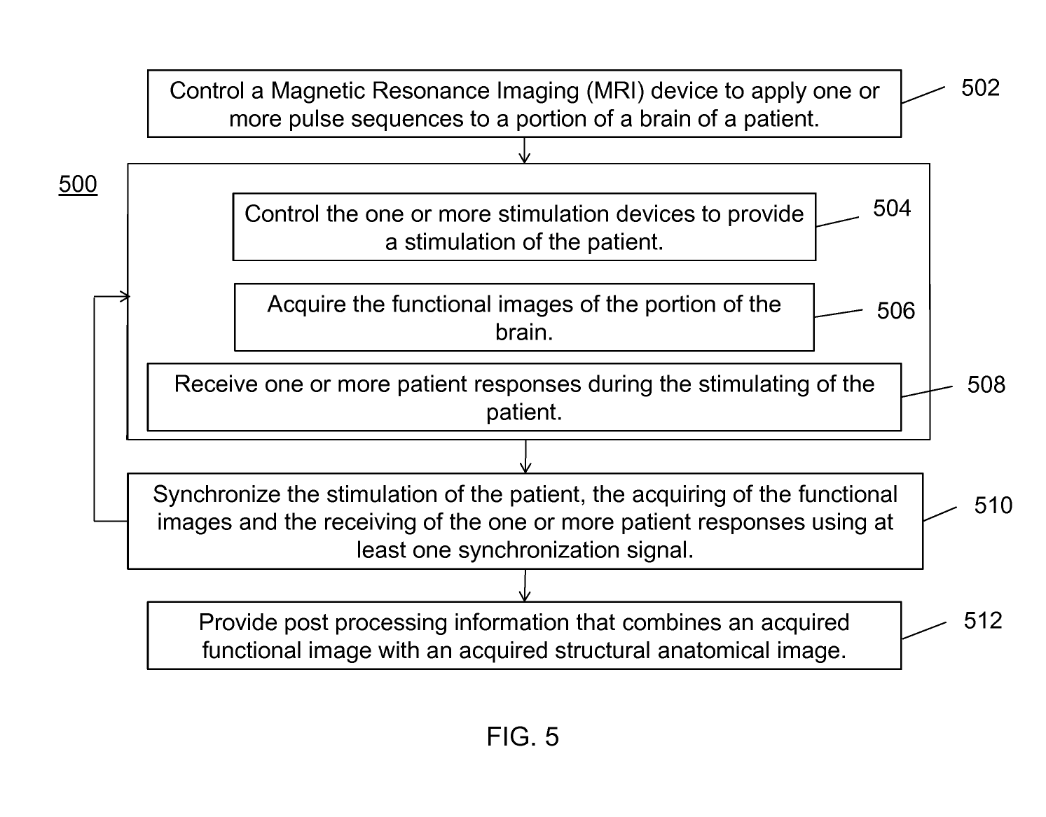

FIG. 5 is a flow diagram illustrating an exemplary method 500 for operating a fMRI system for use with embodiments disclosed herein. As shown at step 502 in FIG. 5, the method 500 may include controlling, by control computer 104, a Magnetic Resonance Imaging (MRI) device 102 to apply one or more pulse sequences to a portion of a brain of a patient. For example, control computer 104 may control a RF signal generator to generate a RF pulse sequence in anatomy (e.g., a portion of a brain) of a patient, enabling the scanner to subsequently acquire associated RF echo data.

As shown at steps 504, 506, and 508 the method may include controlling, by control computer 104, one or more stimulation devices to provide a stimulation of the patient, acquire functional images of the portion of the brain and receive one or more patient responses during the stimulation based on stored instructions at control computer 104. Steps 504, 506 and 508 may occur in different orders and, in some embodiments, two or three of steps 504, 506 and 508 may occur substantially simultaneously.

For example, at step 504, control computer 104 may control image projection equipment 108 and auditory equipment 109 to provide a stimulation of the patient based on instructions, such as fMRI paradigm settings 118, which may be stored at control computer 104. At step 506, control computer 104 may acquire, from MRI image reconstruction computer 106, functional images of the portion of the brain during stimulation and in response to the applying of one or more pulse sequences. A step 508, control computer 104 may control response measurement equipment 110 to receive one or more patient responses during the stimulation.

As shown at step 510, the method may include synchronizing the stimulation of the patient, the acquiring of the functional images and the receiving of the one or more patient responses using at least one synchronization signal. For example, control computer 104 may utilize an internal system clock 308 to synchronize the timing of: (i) providing of intrinsic stimuli to a patient to perform one or more tasks (illustrated by the first timing pattern 302 at FIG. 3); (ii) acquiring images of a portion of a patient's brain (illustrated at the second timing pattern 304 at FIG. 3); and (iii) receiving response measurements of the patient during simulation (illustrated by the third timing pattern 306 at FIG. 3). As shown at FIG. 3, each task is synchronized with the occurrence of multiple acquired images and a corresponding response measurement.

As shown at step 512, the method may include providing, by the control computer 104, post processing information that combines an acquired functional image with an acquired structural anatomical image. For example, control computer 104 may provide fMRI parametric maps overlaid on structural images 122 based on stored instructions, such as fMRI post processing instructions 120.

Although the invention has been described with reference to exemplary embodiments, it is not limited thereto. Those skilled in the art will appreciate that numerous changes and modifications may be made to the preferred embodiments of the invention and that such changes and modifications may be made without departing from the true spirit of the invention. It is therefore intended that the appended claims be construed to cover all such equivalent variations as fall within the true spirit and scope of the invention.

1. A method for operating an automated functional Magnetic Resonance Imaging (fMRI) system, the method comprising:
controlling, by a control computer, a Magnetic Resonance Imaging (MRI) device to apply one or more pulse sequences to a portion of a brain of a patient;
controlling, by the control computer, one or more stimulation devices to provide a stimulation of the patient;
acquiring, by the control computer, functional images of said portion of said brain of the patient in response to the applying of the one or more pulse sequences and during stimulation;
receiving, by the control computer, one or more patient responses during the stimulating of the patient; and
synchronizing, by the control computer, the stimulation of the patient, the acquiring of the functional images and the receiving of the one or more patient responses using at least one synchronization signal.

2. A method of claim 1, further comprising providing, by the control computer, post processing information that combines an acquired functional image of said acquired functional images with an acquired structural anatomical image.

3. A method of claim 2, wherein said providing, by the control computer, said post processing information further comprises providing a combined image by aligning, co-registering and combining the acquired functional image of said acquired functional images with the structural anatomical image using a common scanner coordinate framework.

4. A method of claim 2, wherein said providing, by the control computer, said post processing information further comprises providing a combined image by aligning, co-registering and combining the acquired functional image of said acquired functional images with an acquired structural anatomical image using a common scanner coordinate framework.

5. A method of claim 1, wherein said controlling, by the control computer, one or more stimulation devices to provide a stimulation of a patient comprises controlling a visual presentation device to visually present a cognitive task to the patient.

6. A method of claim 5, wherein said controlling a visual presentation device to visually present a cognitive task to the patient further comprises controlling said visual presentation device to at least one of: (a) vary light in an MRI scanner bore; (b) output the cognitive task to a video device mounted in said MRI scanner bore; and (c) project the cognitive task onto a screen such that the cognitive task is viewable by said patient.

7. A method of claim 1, wherein said controlling, by the control computer, one or more stimulation devices to provide a stimulation of a patient comprises controlling a sound reproduction device to provide a sensory or cognitive auditory based task to said patient.

8. A method of claim 7, wherein said controlling a sound reproduction device further to provide a sensory or cognitive auditory based task to said patient further comprises controlling said sound reproduction device to provide predetermined voice commands issued through an audio system to guide the patient through tasks including at least one of motor tasks, speech tasks, memory tasks and auditory tasks.

9. A method of claim 1, wherein said receiving, at the control computer, one or more patient responses during the stimulating of the patient further comprises receiving a patient electrocardiogram (ECG).

10. A method of claim 1, wherein said synchronizing, by the control computer, further comprises deriving said at least one synchronization signal from a single system clock signal.

11. An automated functional Magnetic Resonance Imaging (fMRI) system, comprising:
a patient stimulation device configured to stimulate a patient;
a Magnetic Resonance Imaging (MRI) acquisition device configured to acquire functional images of a portion of a brain of said patient in response to a pulse sequence and during stimulation by said stimulation device;
a stimulation response measurement device configured to record patient response to said stimulation during said stimulation by said stimulation device; and
a control computer configured to mutually synchronize:
application of stimulation to said patient by said stimulation device;
acquisition of magnetic resonance (MR) images by said MRI acquisition device, and
recording patient response to said stimulation, using at least one synchronization signal.

12. A system according to claim 11, wherein said patient stimulation device configured to stimulate said patient comprises a visual presentation device for presenting a cognitive task to said patient.

13. A system according to claim 11, wherein said patient stimulation device configured to stimulate said patient comprises a sound reproduction device for providing a sensory or cognitive auditory based task to said patient.

14. A system according to claim 11, wherein said patient stimulation device is controlled automatically by an MRI scanner console.

15. A system according to claim 11, wherein said stimulation response measurement device records and gauges patient response during a stimulation task in response to patient interaction with at least one of (a) a pneumatic squeeze ball, (b) a respiratory bellows and (c) a separate response measurement device using, buttons, mouse or joystick.

16. A system according to claim 11, wherein the control computer further comprises:
a repository having structural anatomical image data of said portion of said brain; and
an image data processor configured to align, co-register, and combine an acquired functional image of said portion of said brain with a structural anatomical image acquired from said repository,
wherein said acquired functional image and said structural anatomical image are acquired using a common scanner coordinate framework to provide a combined image.

17. A system according to claim 16, wherein said image data processor applies functions including at least one of, (a) motion correction, (b) slice timing correction, (c) image spatial smoothing, (d) temporal filtering and (e) linear model fitting, to said acquired functional data to form a functional map.

18. A system according to claim 16, wherein said image data processor applies a predetermined threshold to the functional image data in determining brain areas active in response to said stimulation and applies a visual attribute to the determined active brain areas.

19. A system according to claim 16, wherein said image data processor derives and associates a confidence level to the determined active brain areas indicating a degree of confidence in identified active brain area being active in response to said stimulation.

20. A system according to claim 16, wherein
said image data processor applies a plurality of predetermined thresholds to the functional image data in determining brain areas active in response to said stimulation and applies visual attributes to the determined active brain areas distinguishing relative degree of activity of said brain areas, and
said visual attributes comprise at least one of, color, highlighting, shading, patterns and symbols.

21. A system according to claim 11, wherein the control computer further comprises:
a repository including structural anatomical image data of said portion of said brain; and
an image data processor configured to align, co-register, and combine an acquired functional image of said portion of said brain and a structural anatomical image acquired from said repository with a common space,
wherein said acquired functional image and said structural anatomical image are acquired using a common scanner coordinate framework.

22. An article of manufacture for operating an automated functional Magnetic Resonance Imaging (fMRI) system, the article of manufacture comprising a non-transitory, tangible computer-readable medium holding computer-executable instructions for performing a method comprising:
controlling a Magnetic Resonance Imaging (MRI) device to apply one or more pulse sequences to a portion of a brain of a patient;
controlling one or more stimulation devices to provide a stimulation of the patient;
acquiring functional images of said portion of said brain of the patient in response to the applying of the one or more pulse sequences and during stimulation;
receiving one or more patient responses during the stimulating of the patient; and
synchronizing the stimulation of the patient, the acquiring of the functional images and the receiving of the one or more patient responses using at least one synchronization signal.
